(19) United States
(12) Patent Application Publication
(10) Pub. No.: US 2026/0113874 A1
(43) Pub. Date: Apr. 23, 2026

(54) COOLING DISTRIBUTION UNIT WITH QUICK CHANGE CONNECTIONS

(71) Applicant: LTI Holdings, Inc., Pleasanton, CA (US)

(72) Inventors: Steven J. Medeiros, Loudon, NH (US); Jeffrey A. Henning, Exeter, NH (US); Tristan G. Whiting, Watertown, MA (US); Peter H. Hildebrand, Haverhill, NH (US)

(21) Appl. No.: 19/359,930

(22) Filed: Oct. 16, 2025

Related U.S. Application Data
(60) Provisional application No. 63/708,577, filed on Oct. 17, 2024.

(51) Int. Cl. H05K 7/20

(52) U.S. Cl. CPC H05K 7/20272; H05K 7/20263

(57) ABSTRACT

A cooling distribution unit includes a heat exchanger, a primary closed loop configured to circulate a first fluid through the heat exchanger, and a secondary closed loop configured to circulate a second fluid to be cooled by the first fluid through the heat exchanger. The primary closed loop includes a first outlet pipe and a first inlet pipe, which are both selectively rotatable between the first orientation and the second orientation. The first fluid is configured to flow from the first outlet pipe into a cooling structure and from the cooling structure into the first inlet pipe. The secondary closed loop includes a second outlet pipe and a second inlet pipe, which are both selectively rotatable between the first orientation and the second orientation. The second fluid is configured to flow from the second outlet pipe into an electrical component and from the electrical component into the second inlet pipe.

### CROSS-REFERENCE TO RELATED APPLICATIONS

This application claims priority to U.S. Provisional Application No. 63/708,577, filed October 17, 2024, the entire contents of which are incorporated herein by reference.

### FIELD

The present disclosure generally relates to cooling distribution units for directing heat away from electrical components.

### BACKGROUND

Cooling distribution units (commonly referred to as CDU’s) are often utilized in data centers to remove heat from computer components (e.g., servers and server racks). Cooling distribution units may include, for example, both in-row units and in-rack units. In-row units remove heat from an entire row of server racks or other sets of electrical components, while in-rack units typically remove heat from a single rack or set of electrical components.

### SUMMARY

In accordance with one example, a cooling distribution unit includes a heat exchanger, a primary closed loop configured to circulate a first fluid through the heat exchanger, and a secondary closed loop configured to circulate a second fluid through the heat exchanger. The second fluid is configured to be cooled by the first fluid. The primary closed loop includes a first outlet pipe selectively rotatable between a first orientation and a second orientation and a first inlet pipe selectively rotatable between the first orientation and the second orientation. The first fluid is configured to flow from the first outlet pipe into a cooling structure. The first fluid is configured to flow from the cooling structure into the first inlet pipe. The secondary closed loop includes a second outlet pipe selectively rotatable between the first orientation and the second orientation and a second inlet pipe selectively rotatable between the first orientation and the second orientation. The second fluid is configured to flow from the second outlet pipe into an electrical component. The second fluid is configured to flow from the electrical component into the second inlet pipe.

The details of one or more aspects of the disclosure are set forth in the accompanying drawings and the description below. Other features, objects, and advantages of the techniques described in this disclosure will be apparent from the description and drawings, and from the claims.

### BRIEF DESCRIPTION OF THE DRAWINGS

FIG. 1 is a schematic view of a cooling distribution unit in accordance with one example.

FIG. 2 is a perspective view of the cooling distribution unit of FIG. 1.

FIG. 3 is another perspective view of the cooling distribution unit of FIG. 1.

FIG. 4 is another perspective view of the cooling distribution unit of FIG. 1

FIG. 5 is a schematic view of piping of the cooling distribution unit of FIG. 1 in a first orientation.

FIG. 6 is a schematic view of the piping of FIG. 5 in a second orientation.

### DETAILED DESCRIPTION

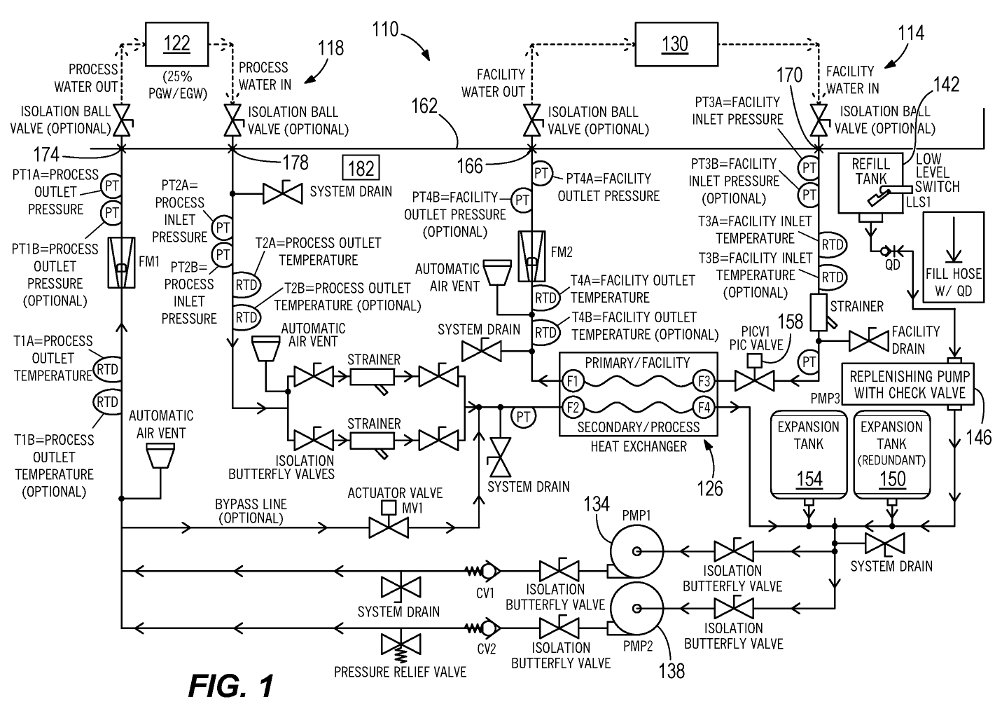

FIGS. 1-4 illustrate an example of a cooling distribution unit 110. The cooling distribution unit 110 may be used in any of a variety of settings, including for example in a server, data center, medical, semiconductor, and/or industrial application. The illustrated cooling distribution unit 110 is an in-row unit, although any of the concepts described herein related to the cooling distribution unit 110 may alternatively be used with an in-rack unit, or with any other type of cooling distribution unit.

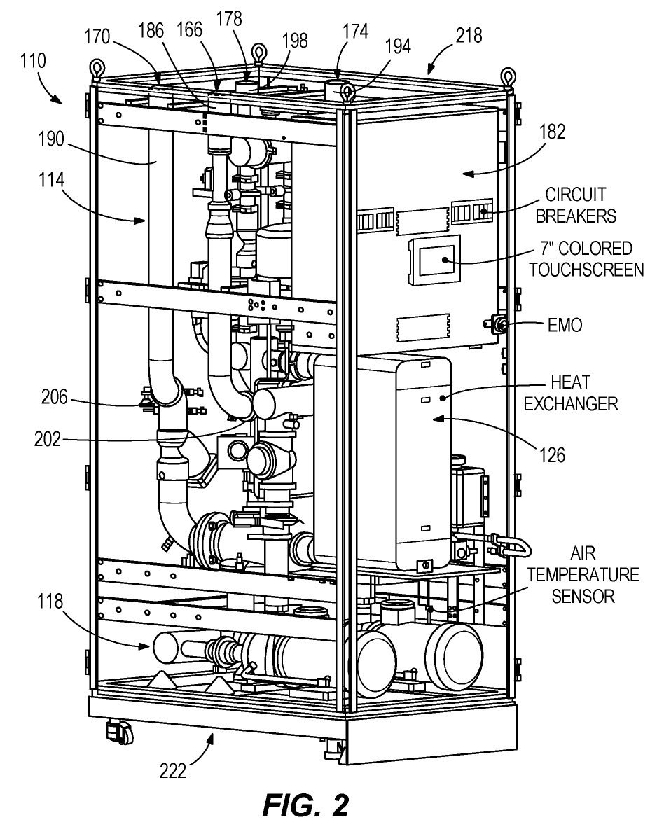

With reference to FIG. 1, the cooling distribution unit 110 generally includes a primary closed loop 114 and a secondary closed loop 118. The primary closed loop 114 circulates a first fluid (e.g., facility water located and/or otherwise supplied at a data server center). The secondary closed loop 118 circulates a second fluid (e.g., a process water solution that includes 25% propylene glycol and 75% water). Other examples include different first and second fluids within either of the primary closed loop 114 or the secondary closed loop 118. As illustrated in FIGS. 2-4, the primary closed loop 114 includes piping (e.g., stainless steel piping) through which the first fluid circulates. The secondary closed loop 118 similarly includes piping (e.g., stainless steel piping) through which the second fluid circulates. In some examples, at least a portion of the piping for the primary closed loop 114 and/or the secondary closed loop 118 is cylindrical in shape and/or has a circular cross-section. In some examples, at least a portion of the piping for the primary closed loop 114 and/or the secondary closed loop 118 has a linear section and/or a curved section. Other examples include other types of piping, including piping made of other materials (e.g., metal or non-metal), or having other shapes and configurations than that illustrated.

In some examples, the first fluid may be composed of or include water or propylene glycol-water solutions having a 50% maximum concentration. In other words, the concentration of the glycol-water solution may have a maximum concentration of 10 mg/L. The second fluid may be composed of or include water or a premixed solution of uninhibited ethylene-glycol or propylene-glycol and water. The first fluid and the second fluid may have a largest particle size of less than 200 microns. Other examples may include other materials and/or compositions of materials and/or particle sizes for the first fluid and/or the second fluid.

With continued reference to FIG. 1, the secondary closed loop 118 circulates the second fluid through and/or across one or more electrical components 122, to pick up heat from the electrical components 122. The electrical components 122 may include, for example, computer chips or other heated electrical components in one or more servers or server racks. In some examples, cold plates or other thermal devices may be positioned over the computer chips, and the piping of the secondary closed loop 118 may pass through the cold plates or other thermal devices to pick up the heat from the electrical components 122. Once the second fluid in the secondary closed loop 118 has been heated by the electrical components 122, the heated second fluid is directed to a heat exchanger 126.

With continued reference to FIG. 1, each of the primary closed loop 114 and the secondary closed loop 118 extends through the heat exchanger 126. In the illustrated example, the heat exchanger 126 is a liquid-to-liquid heat exchanger. The primary closed loop 114 directs the first fluid in a first direction (e.g., to the left as viewed in FIG. 1) through the heat exchanger 126, and the secondary closed loop 118 directs the second fluid in a second direction (e.g., to the right as viewed in FIG. 1) through the heat exchanger 126. In the illustrated example, the first direction is parallel to, and opposite, the first direction. In other examples the first fluid and the second fluid may be directed in the same direction, or in a transverse direction, or the first and second fluids may be moved in more than one direction in the heat exchanger 126.

Within the heat exchanger 126, heat is exchanged between the second fluid and the first fluid. Accordingly, at least a portion of the heat picked up from the electrical components 122 is transferred from the second fluid to the first fluid within the heat exchanger 126. In some examples, the piping of the primary closed loop 114 does not contact the piping of the secondary closed loop 118 within the heat exchanger 126, and the heat is exchanged through an intermediary material (e.g., through a thermally conductive material). Other examples may include various other types or numbers or arrangements of heat exchangers 126 than that illustrated.

With continued reference to FIG. 1, the primary closed loop 114 directs the first fluid (after having been heated in the heat exchanger 126) away from the heat exchanger 126, and to a cooling structure 130. The cooling structure 130 may be located for example within a data server center. The cooling structure 130 may be any of a variety of different structures, including a cooling tower or other thermal device that sheds or otherwise removes heat from the first fluid. In some examples, the cooling structure 130 may include a cold plate, fins, and/ or other structures that remove heat, and/or may use a fan or fans to facilitate removal of heat from the first fluid.

As illustrated in FIG. 1, once the heat has been removed from the first fluid at the cooling structure 130, the first fluid is then circulated back toward the heat exchanger 126. Similarly, once the heat has been removed from the second fluid at the heat exchanger 126, the second fluid is circulated back toward the electrical components 122. This circulation through each of the primary closed loop 114 and the secondary closed loop 118 may continue (e.g., for as long as the electrical components 122 are generating heat), such that heat is continuously picked up from the electrical components and delivered to the heat exchanger 126, where the heat is then transferred to the first fluid and the primary closed loop 114, and eventually discarded at the cooling structure 130.

With continued reference to FIG. 1, each of the primary closed loop 114 and the secondary closed loop 118 may include one or more pumps to pump the first fluid and the second fluid through the piping. In the illustrated example, the primary closed loop 114 includes one or more pumps (not illustrated) located within the data server center (e.g., at the location of the cooling structure 130, or elsewhere within the data server center, to pump the first fluid (e.g., facility water) through the primary closed loop 114. The secondary closed loop 118 includes both a first pump 134 and a second pump 138. The first and second pumps 134, 138 are redundant pumps, positioned along parallel lines within the closed loop, such that if one of the pumps fails, the other may continue to operate the overall flow of the second fluid within the secondary closed loop 118. The first pump 134 and the second pump 138 may be any type of pump that is capable of pumping the second fluid. In some examples, the first pump 134 and the second pump 138 are identical pumps, having a same size and/or rating. In some examples, one or more of the first pump 134 or the second pump 138 is a centrifugal pump. Other examples include other types of pumps, and also numbers of pumps. For example, secondary closed loop 118 may in some examples include only a single pump, or may include more than two pumps. Overall, the first pump 134 and/or the second pump 138 may generate a flow rate of for example between 25 gallons per minute (GPM) and 200 GPM (e.g., 25 GPM, 50GPM, 100GPM, 125 GPM, 140 GPM, 160 GPM, or other values and ranges of values).

With continued reference to FIG. 1, in some examples the secondary closed loop 118 includes a refill tank 142 and a replenishing pump 146, for adding additional second fluid into the secondary closed loop 118. Additionally, in some examples the secondary closed loop 118 includes at least one expansion tank, for controlling an overall pressure and flow of the second fluid in the secondary closed loop 118. In the illustrated example, the secondary closed loop 118 includes a first expansion tank 150 and a second (e.g., redundant) expansion tank 154. Other examples may include just a single expansion tank, or more than two expansion tanks.

Additionally, both the primary closed loop 114 and the secondary closed loop 118 may include one or more valves (e.g., pressure control valves, check valves, pressure independent control valves, etc.) that operate to control the overall pressure and/or flow of fluid through the cooling distribution unit 110. In the illustrated example, the primary closed loop 114 includes a pressure independent control valve 158.

With continued reference to FIG. 1, in the illustrated example, the cooling distribution unit 110 includes a housing 162 (e.g., an outer housing). The housing 162 may include a steel frame e.g., with interconnected vertical and/or horizontal frame members), or may be another type of frame, or be formed from different materials. In some examples, the housing 162 = includes one or more doors (e.g., pivotally coupled or otherwise coupled to the frame). Other examples may include various other types, sizes, and/or shapes of housing 162 than that illustrated. In the illustrated example, the housing 162 includes a first outlet 166 where the primary closed loop 114 exits, and the first fluid is sent to the cooling structure 130. The housing 162 also includes a first inlet 170, wherein the primary closed loop 114 enters, and wherein the first fluid is then directed to the heat exchanger 126 (e.g., located within the housing 162). The housing 162 also includes a second outlet 174, where the secondary closed loop 118 exits and the second fluid is sent to the electrical components 122, and a second inlet 178, where the second fluid enters and is then directed to the heat exchanger 126.

With continued reference to FIG. 1, in some examples, the cooling distribution unit 110 additionally includes one or more sensors that measure pressure, temperature, or other aspects of the system. In the illustrated example, the cooling distribution unit 110 includes a plurality of pressure and temperature sensors (labeled as “PT” and “RTD” in FIG. 1) that are positioned generally at the first outlet 166, the first inlet 170, the second outlet 174, and the second inlet 178. As illustrated in FIG. 1, the cooling distribution unit 110 may include redundant pressure and temperature sensors (e.g., in the event one or more of the sensors fails or provide inaccurate readings).

In some examples, these sensors are coupled (e.g., wired or wirelessly) to a controller 182 (FIGS. 1-4) or other device that receives signals regarding the pressure and temperature of the first fluid and the second fluid. In the illustrated example, the controller 182 is located on and/or within the housing 162, and may include a user interface (e.g., graphical user interface, such as a color touchscreen). In some examples, the controller 182 is located remotely from the housing 162. In some examples, the controller 182 may be used to monitor pressure, monitor temperature, and/or control a flow and pressure differential of the second fluid.

With reference to FIG. 2, the piping of the primary closed loop 114 includes a first outlet pipe 186 and a first inlet pipe 190. The first outlet pipe 186 may include one or more regions that extend linearly (e.g., along an axis) and/or one or more regions that are curved. Similarly, the first inlet pipe 190 may include one or more regions that extend linearly (e.g., along an axis) and/or one or more regions that are curved. The first outlet pipe 186 defines the first outlet 166, and the first inlet pipe 190 defines the first inlet 170. The first fluid flows from the first outlet pipe 186 into the cooling structure 130 and from the cooling structure 130 into the first inlet pipe 190. The piping of the secondary closed loop 118 includes a second outlet pipe 194 and a second inlet pipe 198. The second outlet pipe 194 may include one or more regions that extend linearly (e.g., along an axis) and/or one or more regions that are curved. Similarly, the second inlet pipe 198 may include one or more regions that extend linearly (e.g., along an axis) and/or one or more regions that are curved. The second outlet pipe 194 defines the second outlet 174, and the second inlet pipe 198 defines the second inlet 178. The second fluid flows from the second outlet pipe 194 into the one or more electrical components 122 and from the one or more electrical components 122 into the second inlet pipe 198. The first outlet pipe 186, the first inlet pipe 190, the second outlet pipe 194, and the second inlet pipe 198 can be cylindrical sanitary stainless steel piping. Other examples include different types of piping, including piping made of other materials, or having other shapes and sizes and configurations than that illustrated.

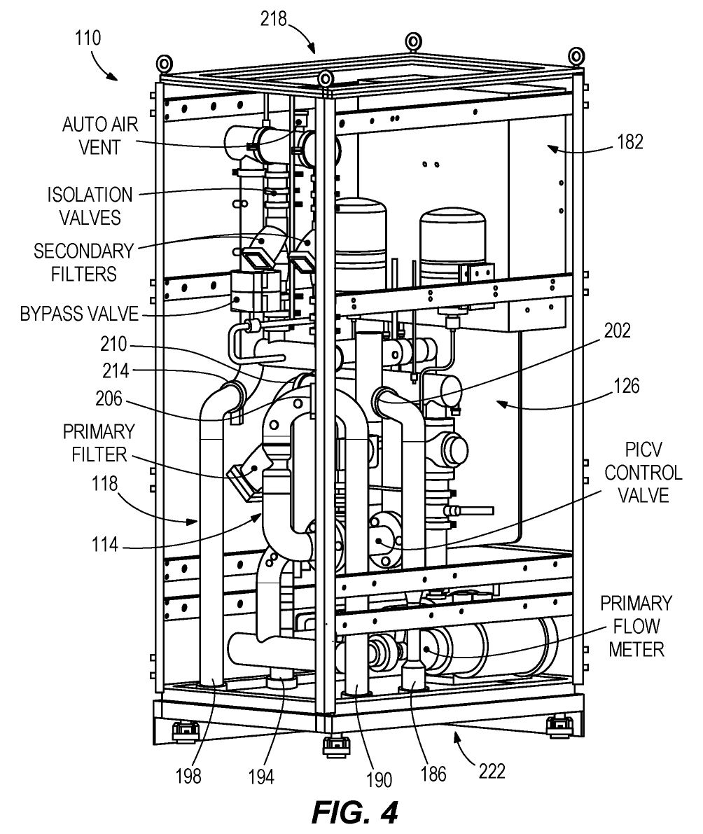

As best illustrated in FIG. 4, the first outlet pipe 186 is coupled to other piping in the primary closed loop 114 by a first outlet clamp 202, and the first inlet pipe 190 is coupled to the other piping in the primary closed loop 114 by a first inlet clamp 206. Similarly, the second outlet pipe 194 is coupled to the other piping in the secondary closed loop 118 by a second outlet clamp 210, and the second inlet pipe 198 is coupled to the other piping in the secondary closed loop 118 by a second inlet clamp 214. In some examples, the first outlet clamp 202, first inlet clamp 206, second outlet clamp 210, and second inlet clamp 214 are identical sanitary tri-clamps (e.g., modular clamps having a same size and/or shape). Other examples include different types of clamps, and/or include individual clamps being different from one another. Overall, the clamps described herein may be any structures that are generally adjustable between a first state that allows relative movement (e.g., rotation) of pipe components and a second state that inhibits or prevents relative movement between pipe components.

With reference to FIGS. 2-4, the piping of the primary closed loop 114 and the secondary closed loop 118 is selectively rotatable or adjustable to change the orientation of the pipes and the locations of the first outlet 166, the first inlet 170, the second outlet 174, and the second inlet 178. More specifically, the first outlet pipe 186, the first inlet pipe 190, the second outlet pipe 194, and the second inlet pipe 198 are each adjustable to change the location of the first outlet 166, the first inlet 170, the second outlet 174, and the second inlet 178, respectively. The locations of the first outlet 166, the first inlet 170, the second outlet 174, and the second inlet 178 are desirably adjustable to allow for customization of the cooling distribution unit 110. By having adjustable piping, the cooling distribution unit 110 can be used in a variety of applications and can be quickly and easily adjusted or manipulated to meet requirements for the locations of the first outlet 166, the first inlet 170, the second outlet 174, and/or the second inlet 178.

In one example, the hookups or connections for the cooling structure 130 may be positioned above the cooling distribution unit 110. In this example, it is desired to have the first outlet 166 and the first inlet 170 extending through a top 218 of the cooling distribution unit 110. In another example, the hookups or connections for the cooling structure 130 may be positioned below the cooling distribution unit 110. In this example, it is desired to have the first outlet 166 and the first inlet 170 extending through a bottom 222 of the cooling distribution unit 110. In each of these examples, if the piping was not easily adjustable, the piping would have to be, for example, cut and welded to the proper orientation. Cutting and welding to adjust the piping orientation undesirably takes time, effort, energy, and resources.

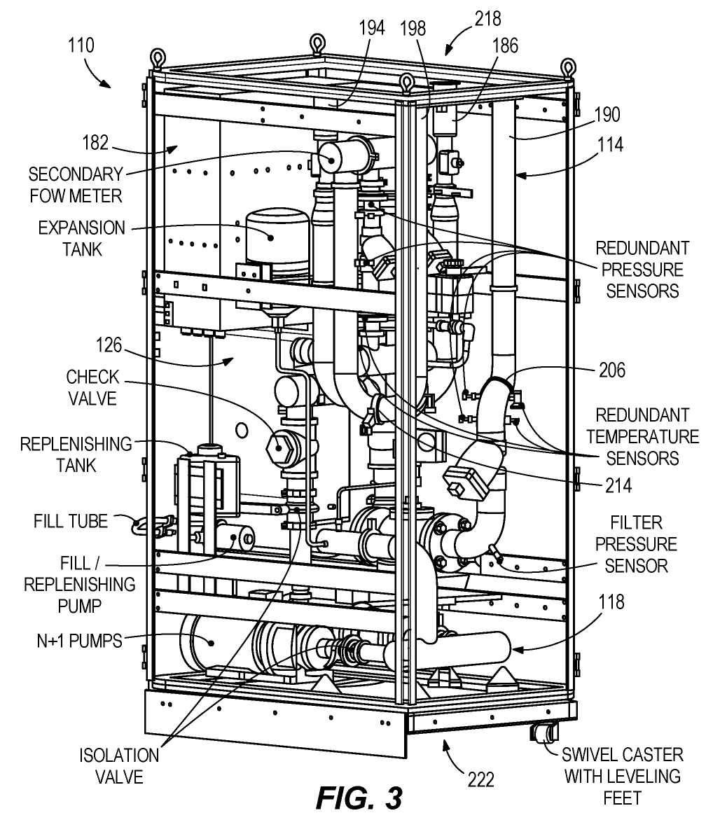

With reference to FIGS. 2 and 3, the piping of the primary closed loop 114 and the secondary closed loop 118 extends toward the top 218 of the cooling distribution unit 110. As such, each of the first outlet pipe 186, the first inlet pipe 190, the second outlet pipe 194, and the second inlet pipe 198 is in a first orientation. The first orientation is defined as extending vertically upward or toward the top 218 of the cooling distribution unit 110. More specifically, each of the first outlet pipe 186, the first inlet pipe 190, the second outlet pipe 194, and the second inlet pipe 198 extends from the respective first outlet clamp 202, the first inlet clamp 206, the second outlet clamp 210, and the second inlet clamp 214 toward the top 218 of the cooling distribution unit 110. In the illustrated example, the first outlet 166, the first inlet 170, the second outlet 174, and the second inlet 178 are positioned adjacent the top 218 of the cooling distribution unit 110. In some examples, the first outlet 166, the first inlet 170, the second outlet 174, and the second inlet 178 can be positioned just below the top 218 of the cooling distribution unit 110. In other examples, the first outlet 166, the first inlet 170, the second outlet 174, and the second inlet 178 can be positioned just above the top 218 of the cooling distribution unit 110.

With reference to FIG. 4, in some examples the piping of the primary closed loop 114 and the secondary closed loop 118 extends toward the bottom 222 of the cooling distribution unit 110. Each of the first outlet pipe 186, the first inlet pipe 190, the second outlet pipe 194, and the second inlet pipe 198 is in a second orientation. The second orientation is defined as extending vertically downward or toward the bottom 222 of the cooling distribution unit 110. More specifically, each of the first outlet pipe 186, the first inlet pipe 190, the second outlet pipe 194, and the second inlet pipe 198 extends from the respective first outlet clamp 202, the first inlet clamp 206, the second outlet clamp 210, and the second inlet clamp 214 toward the bottom 222 of the cooling distribution unit 110.

In the illustrated example, the first outlet 166, the first inlet 170, the second outlet 174, and the second inlet 178 are positioned adjacent the bottom 222 of the cooling distribution unit 110. In some examples, the first outlet 166, the first inlet 170, the second outlet 174, and the second inlet 178 can be positioned just below the bottom 222 of the cooling distribution unit 110. In other examples, the first outlet 166, the first inlet 170, the second outlet 174, and the second inlet 178 can be positioned just above the bottom 222 of the cooling distribution unit 110.

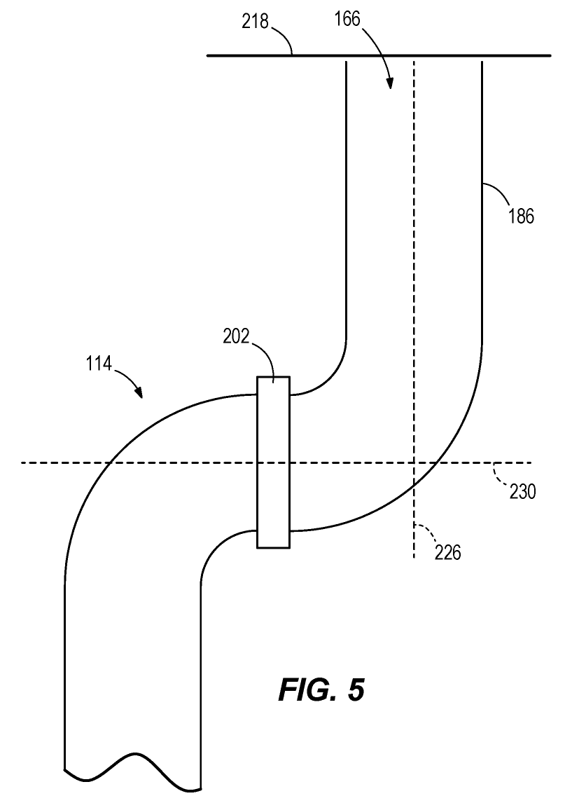

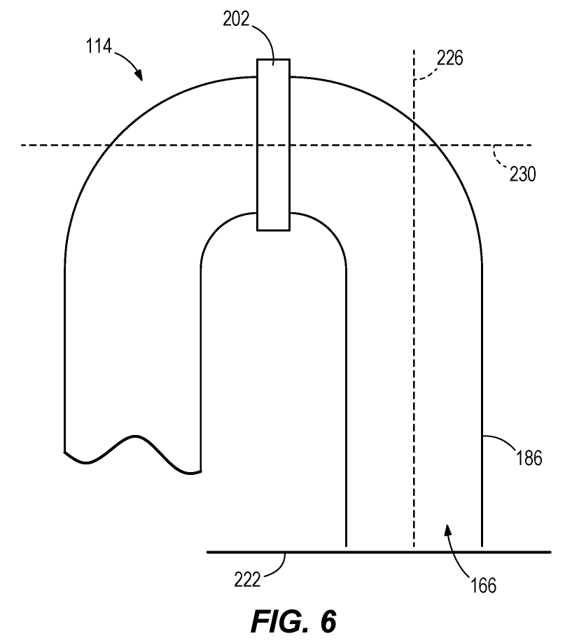

With reference to FIGS. 5 and 6, the first outlet pipe 186 and the first outlet clamp 202 of the primary closed loop 114 are schematically illustrated. The first outlet pipe 186 extends from the first outlet clamp 202 toward the top 218 of the cooling distribution unit in FIG. 5, and the first outlet pipe 186 extends from the first outlet clamp 202 toward the bottom 222 of the cooling distribution unit in FIG. 6.

With reference to FIG. 5, the first outlet pipe 186 extends along a pipe axis 226. In the illustrated example, the pipe axis 226 extends vertically or between the top 218 and the bottom 222 (only the top 218 shown in FIG. 5). The pipe axis 226 extends perpendicular to surfaces defined by the top 218 and the bottom 222. In other examples, the pipe axis 226 can extend in other directions. For example, the pipe axis 226 can extend obliquely to the surfaces defined by the top 218 and the bottom 222. The first outlet clamp 202 defines a clamp axis 230. The clamp axis 230 is defined through a center of the first outlet clamp 202. In some examples, the first outlet clamp 202 is cylindrical. In these examples, the clamp axis 230 is defined as a line extending through the center of the cylindrical first outlet clamp 202. In the illustrated example, the clamp axis 230 extends horizontal or parallel to the surfaces defined by the top 218 and the bottom 222. In other examples, the clamp axis 230 can extend in other directions. For example, the clamp axis 230 can extend obliquely relative to the surfaces defined by the top 218 and the bottom 222. In the illustrated example, the pipe axis 226 and the clamp axis 230 are perpendicular. In other examples, the pipe axis 226 and the clamp axis 230 can be oblique or parallel to each other.

With reference to FIG. 6, the pipe axis 226 extends perpendicular to surfaces defined by the top 218 and the bottom 222 (only the bottom 222 shown in FIG. 6). In other examples, the pipe axis 226 can extend in other directions. For example, the pipe axis 226 can extend obliquely to the surfaces defined by the top 218 and the bottom 222. In the illustrated example, the clamp axis 230 extends horizontal or parallel to the surfaces defined by the top 218 and the bottom 222. In other examples, the clamp axis 230 can extend in other directions. For example, the clamp axis 230 can extend obliquely to the surfaces defined by the top 218 and the bottom 222. In the illustrated example, the pipe axis 226 and the clamp axis 230 are perpendicular. In other examples, the pipe axis 226 and the clamp axis 230 can be oblique or parallel to each other. It should be appreciated that the first inlet pipe 190 and the first inlet clamp 206, the second outlet pipe 194 and the second outlet clamp 210, and the second inlet pipe 198 and the second inlet clamp 214 can have any of the features, function, relative orientation, or interaction as described herein with reference to the first outlet pipe 186 and the first outlet clamp 202.

Prior to assembly of setup of the cooling distribution unit 110, the cooling distribution unit 110 may be introduced into a data center, factory, warehouse, or any other location where the cooling distribution unit 110 is desired. The location may have pre-built infrastructure that includes, for example, the electrical components 122 and/or the cooling structure 130. As such, the electrical components 122 and/or the cooling structure 130 may be permanent or immovable. Accordingly, the location of each of the first outlet 166, the first inlet 170, the second outlet 174, and the second inlet 178 must be optimized to properly connect to the respective electrical components 122 and cooling structure 130. The location of each of the first outlet 166, the first inlet 170, the second outlet 174, and the second inlet 178 may be optimized when each of the first outlet 166, the first inlet 170, the second outlet 174, and the second inlet 178 is adjacent or substantially close to the desired connection in the respective electrical components 122 or the cooling structure 130. It may be undesirable to, for example, connect the first outlet 166 to the cooling structure 130 with an additional hose that may be long (e.g., 10 feet). Rather, it may be desirable to place the first outlet 166 sufficiently close to the cooling structure 130 to directly connect the first outlet pipe 186 to the cooling structure 130 or only require a small additional connection piece (e.g., one foot, 6 inches, etc.) to fluidly connect the first outlet pipe 186 to the cooling structure 130. It should be appreciated that a similar direct or close connection may be desired between the first inlet 170 and the cooling structure 130, the second outlet 174 and the electrical components 122, and the second inlet 178 and the electrical components 122 as described with reference to the first outlet 166 and the cooling structure 130.

During assembly or setup of the cooling distribution unit 110, the user can determine the desired orientation of each of the first outlet pipe 186, the first inlet pipe 190, the second outlet pipe 194, and the second inlet pipe 198. The desired orientation of each of the first outlet pipe 186, the first inlet pipe 190, the second outlet pipe 194, and the second inlet pipe 198 can be the first orientation (as shown in FIGS. 2, 3, and 5) or the second orientation (as shown in FIGS. 4 and 6). In some examples, each desired orientation may be the same, such as in FIGS. 2-4. In FIGS. 2 and 3, each of the first outlet pipe 186, the first inlet pipe 190, the second outlet pipe 194, and the second inlet pipe 198 are in the first orientation. In FIG. 4, each of the first outlet pipe 186, the first inlet pipe 190, the second outlet pipe 194, and the second inlet pipe 198 are in the second orientation. In other examples, each desired orientation may be different. For example, the first outlet pipe 186 and the first inlet pipe 190 can be in the first orientation (as shown in FIGS. 2 and 3) and the second outlet pipe 194 and the second inlet pipe 198 may be in the second orientation (as shown in FIG. 4). As another example, the first outlet pipe 186 and the first inlet pipe 190 may be in the second orientation and the second outlet pipe 194 and the second inlet pipe 198 may be in the first orientation. As yet another example, the first outlet pipe 186 may be in the second orientation, and the first inlet pipe 190, the second outlet pipe 194, and the second inlet pipe 198 may be in the first orientation. It should be appreciated that other examples exist in which the first outlet pipe 186, the first inlet pipe 190, the second outlet pipe 194, and the second inlet pipe 198 are in the first orientation, the second orientation, or in any other orientation. It should further be appreciated that other examples exist in which each of the first outlet pipe 186, the first inlet pipe 190, the second outlet pipe 194, and the second inlet pipe 198 are in different orientations.

Once the desired orientations are determined, the user can adjust each of the first outlet pipe 186, the first inlet pipe 190, the second outlet pipe 194, and the second inlet pipe 198 to achieve each respective desired orientation. The user can adjust each pipe by loosening the respective clamp, rotating the pipe, and then tightening the clamp. For example, to rotate the first outlet pipe 186, the first outlet clamp 202 may first be loosened and/or removed. Once the first outlet clamp 202 is sufficiently loosened and/or removed, the first outlet pipe 186 may be rotated (e.g., about the clamp axis 230 or other axis) relative to the rest of the piping of the primary closed loop 114 (e.g., by 45 degrees, 90 degrees, 135 degrees, 180 degrees, 225 degrees, 270 degrees, between 135 degrees and 225 degrees, or other values or ranges of values). Once the first outlet pipe 186 is at the desired orientation, the first outlet clamp 202 can be re-tightened or coupled to the first outlet pipe 186 to secure the first outlet pipe 186 to the rest of the primary closed loop 114. It should be appreciated that the same steps can be taken to rotate the first inlet pipe 190, the second outlet pipe 194, and/or the second inlet pipe 198 as described with reference to the first outlet pipe 186.

Once each of the first outlet pipe 186, the first inlet pipe 190, the second outlet pipe 194, and the second inlet pipe 198 is in the desired orientation, the first outlet pipe 186 and the first inlet pipe 190 may be connected to the cooling structure 130 to complete the primary closed loop 114. Similarly, the second outlet pipe 194 and the second inlet pipe 198 may be connected to the electrical components 122 to complete the secondary closed loop 118.

In the illustrated example, the cooling distribution unit 110 has an overall dimension of 31.5” by 47.4” by 84.5”, and an overall weight of approximately 1400 pounds. Other examples may include various different sizes and weights, including sizes smaller and larger than that illustrated, and weights smaller or greater than that illustrated. Additionally, in the illustrated example, the cooling distribution unit 110 may provide a cooling capacity of 550kW (at 4ºC approach temperature difference) and 1100kW (at 8ºC approach temperature difference). Other examples may include other values and ranges of values of cooling capacity, including a cooling capacity smaller or greater than that illustrated.

Although various aspects and examples have been described in detail with reference to certain examples illustrated in the drawings, variations and modifications exist within the scope and spirit of one or more independent aspects described and illustrated.

What is claimed is:

1. A cooling distribution unit comprising:
a heat exchanger;
a primary closed loop configured to circulate a first fluid through the heat exchanger, the primary closed loop including
a first outlet pipe selectively rotatable between a first orientation and a second orientation, the first fluid configured to flow from the first outlet pipe into a cooling structure, and
a first inlet pipe selectively rotatable between the first orientation and the second orientation, the first fluid configured to flow from the cooling structure into the first inlet pipe; and
a secondary closed loop configured to circulate a second fluid through the heat exchanger, the second fluid configured to be cooled by the first fluid, the secondary closed loop including
a second outlet pipe selectively rotatable between the first orientation and the second orientation, the second fluid configured to flow from the second outlet pipe to an electrical component, and
a second inlet pipe selectively rotatable between the first orientation and the second orientation, the second fluid configured to flow from the electrical component into the second inlet pipe.

2. The cooling distribution unit of claim 1, wherein the first orientation is extending toward a top of the cooling distribution unit, and wherein the second orientation is extending toward a bottom of the cooling distribution unit.

3. The cooling distribution unit of claim 1, wherein the first outlet pipe is coupled to other piping of the primary closed loop by a first outlet clamp, and wherein the first inlet pipe is coupled to the other piping of the primary closed loop by a first inlet clamp.

4. The cooling distribution unit of claim 3, wherein the second outlet pipe is coupled to other piping of the secondary closed loop by a second outlet clamp, and wherein the second inlet pipe is coupled to the other piping of the secondary closed loop by a second inlet clamp.

5. The cooling distribution unit of claim 4, wherein the first outlet clamp, the first inlet clamp, the second outlet clamp, and the second inlet clamp are identical.

6. The cooling distribution unit of claim 5, wherein each of the first outlet clamp, the first inlet clamp, the second outlet clamp, and the second inlet clamp is a tri-clamp.

7. The cooling distribution unit of claim 1, wherein the first fluid is water, and wherein the second fluid is a solution including 25% propylene glycol and 75% water.

8. The cooling distribution unit of claim 1, wherein the first outlet pipe includes a region that extends linearly.

9. The cooling distribution unit of claim 8, wherein the first outlet pipe includes a region that is curved.

10. The cooling distribution unit of claim 1, wherein the first outlet pipe includes a region having a cylindrical shape.

11. The cooling distribution unit of claim 10, wherein the first outlet pipe includes a region having a circular cross-section.

12. The cooling distribution unit of claim 1, wherein the first outlet pipe is rotatable 180 degrees about a clamp axis between the first orientation and the second orientation.

13. The cooling distribution unit of claim 1, wherein the first outlet pipe is a stainless steel pipe.

14. The cooling distribution unit of claim 1, wherein the heat exchanger is a liquid-to-liquid heat exchanger.

15. The cooling distribution unit of claim 1, wherein the secondary closed loop includes both a first pump and a second pump, wherein the first pump and the second pump are redundant pumps.

16. The cooling distribution unit of claim 1, wherein the first outlet pipe defines a first outlet of the cooling distribution unit, wherein the first inlet pipe defines a first inlet of the cooling distribution unit, wherein the second outlet pipe defines a second outlet of the cooling distribution unit, and wherein the second inlet pipe defines a second inlet of the cooling distribution unit.

17. The cooling distribution unit of claim 16, further comprising a plurality of sensors configured to measure at least one of pressure or temperature.

18. The cooling distribution unit of claim 17, wherein the plurality of sensors are positioned at the first outlet, the first inlet, the second outlet, and the second inlet.

19. The cooling distribution unit of claim 1, wherein each of the first outlet pipe, the first inlet pipe, the second outlet pipe, and the second inlet pipe is in the first orientation.

20. The cooling distribution unit of claim 1, wherein at least one of the first outlet pipe, the first inlet pipe, the second outlet pipe, or the second inlet pipe is in the first orientation, and wherein at least one of the first outlet pipe, the first inlet pipe, the second outlet pipe, and the second inlet pipe is in the second orientation.
